(19) United States
(12) Patent Application Publication
(10) Pub. No.: US 2024/0162067 A1
(43) Pub. Date: May 16, 2024

(54) Substrate Support, Substrate Processing Apparatus and Method of Manufacturing Semiconductor Device

(71) Applicant: Kokusai Electric Corporation, Tokyo (JP)

(72) Inventor: Daiki TANIGUCHI, Toyama (JP)

(21) Appl. No.: 18/417,121

(22) Filed: Jan. 19, 2024

Related U.S. Application Data
(63) Continuation of application No. PCT/JP2021/031214, filed on Aug. 25, 2021.

(51) Int. Cl. H01L 21/673; H01L 21/324; H01L 21/67

(52) U.S. Cl. CPC H01L 21/67306; H01L 21/324; H01L 21/67109

(57) ABSTRACT

There is provided a technique that includes: a top plate made of a metal material; a bottom plate made of a metal material; and a plurality of pillars made of a metal material and provided between the top plate and the bottom plate, wherein a plurality of substrates are supported in a multistage manner by at least a part of the plurality of pillars, wherein relative locations between the top plate and the plurality of pillars and relative locations between the bottom plate and the plurality of pillars are positioned by a plurality of spigot structures, and wherein each of the plurality of pillars and each of the plurality of pillars are removably fixed to the top plate and the bottom plate, respectively, by using a plurality of fixing structures.

### CROSS REFERENCE TO RELATED APPLICATIONS

This application is a bypass continuation application of PCT International Application No. PCT/JP2021/031214, filed on Aug. 25, 2021, in the WIPO, the entire contents of which are hereby incorporated by reference.

### TECHNICAL FIELD

The present disclosure relates to a substrate support, a substrate processing apparatus and a method of manufacturing a semiconductor device.

### BACKGROUND

According to some related arts, as a part of a manufacturing process of a semiconductor device, a film forming process of accommodating a plurality of substrates in a process chamber while being supported in a multistage manner by a substrate support and forming a film on the plurality of substrates accommodated in the process chamber may be performed.

According to some related arts, the plurality of substrates may be supported by the substrate support including: a support column (that is, a plurality of support columns) made of a metal material; and a plurality of support structures provided on the support column (that is, the plurality of support columns) and configured to support the plurality of substrates in the multistage manner.

In the substrate support described above, due to a large width of a pillar such as the support column a local thickness decrease of the film may occur on a portion of each substrate in the vicinity of the support column. This has a negative influence on a film uniformity within a surface of the substrate.

### SUMMARY

According to the present disclosure, there is provided a technique capable of suppressing a thickness decrease of a film around a pillar of a substrate support by reducing a width of the pillar of the substrate support and capable of improving a thickness uniformity of the film.

According to an aspect of the present disclosure, there is provided a technique that includes: a top plate made of a metal material; a bottom plate made of a metal material; and a plurality of pillars made of a metal material and provided between the top plate and the bottom plate, wherein a plurality of substrates are supported in a multistage manner by at least a part of the plurality of pillars, wherein relative locations between the top plate and the plurality of pillars and relative locations between the bottom plate and the plurality of pillars are positioned by a plurality of spigot structures, and wherein each of the plurality of pillars and each of the plurality of pillars are removably fixed to the top plate and the bottom plate, respectively, by using a plurality of fixing structures.

### BRIEF DESCRIPTION OF THE DRAWINGS

FIG. 1 is a diagram schematically illustrating a vertical cross-section of a vertical type process furnace of a substrate processing apparatus according to one or more embodiments of the present disclosure.

FIG. 2 is a diagram schematically illustrating a horizontal cross-section, taken along a line A-A shown in FIG. 1, of the vertical type process furnace.

FIG. 3 is a diagram schematically illustrating a gas supplier of the substrate processing apparatus shown in FIG. 1.

FIG. 4 is a diagram schematically illustrating a perspective view of a substrate support accommodated in the substrate processing apparatus shown in FIG. 1.

FIG. 5 is a diagram schematically illustrating a perspective view of a boat serving as a part of the substrate support shown in FIG. 4.

FIG. 6A is a diagram schematically illustrating a perspective view of a part of an inner side of a support column of the boat, and FIG. 6B is a diagram schematically illustrating a perspective view of a part of an inner side of an auxiliary support column of the boat.

FIG. 7A is a diagram schematically illustrating a horizontal cross-section, taken along a line VII-VII shown in FIG. 6A, of a support structure in the support column, and FIG. 7B is a diagram schematically illustrating a horizontal cross-section, taken along the line VII-VII shown in FIG. 6A, of a modified example of the support structure in the support column.

FIG. 8 is a diagram schematically illustrating a perspective view of a heat insulating plate holder serving as a part of the substrate support shown in FIG. 4.

FIG. 9 is a diagram schematically illustrating a plan view of the substrate support taken along a line IX-IX shown in FIG. 4.

FIG. 10 is a diagram schematically illustrating a vertical cross-section (that is, a cross-section taken along a line X-X shown in FIG. 4) of a fixing portion between the boat and the heat insulating plate holder.

FIG. 11 is a diagram schematically illustrating a vertical cross-section (that is, a cross-section taken along a line XI-XI shown in FIG. 4) of a fixing portion between a top plate and a pillar of the boat.

FIG. 12 is a diagram schematically illustrating a vertical cross-section (that is, a cross-section taken along a line XII-XII shown in FIG. 4) of a fixing portion between a bottom plate and the pillar of the boat.

FIG. 13 is a diagram schematically illustrating a modified example of the fixing portion between the bottom plate and the pillar of the boat.

FIG. 14 is a block diagram schematically illustrating a configuration of a controller and related components of the substrate processing apparatus shown in FIG. 1.

FIG. 15 is a flow chart schematically illustrating an operation of the substrate processing apparatus shown in FIG. 1.

### DETAILED DESCRIPTION

### Embodiments of Present Disclosure

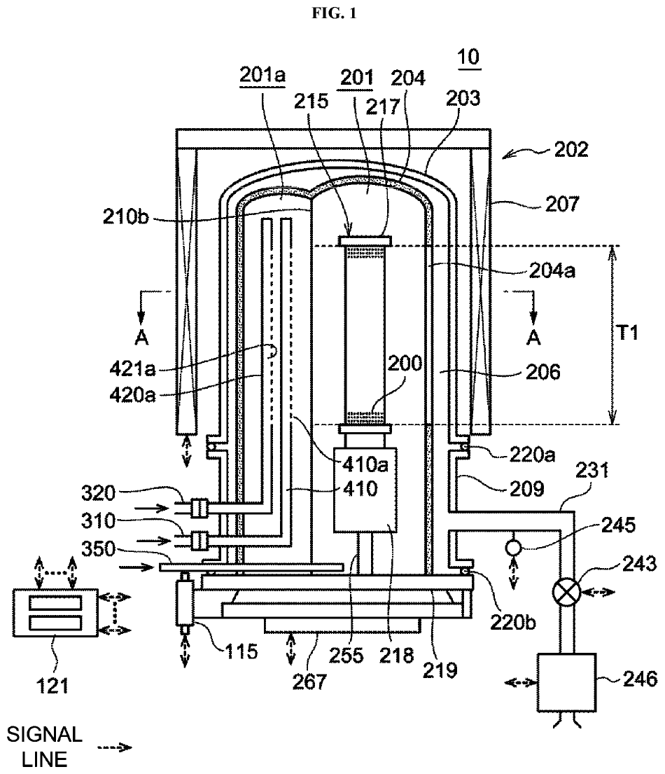

Hereinafter, one or more embodiments (also simply referred to as “embodiments”) of the technique of the present disclosure will be described in detail with reference to FIGS. 1 through 15. A substrate processing apparatus 10 is configured as an example of an apparatus used in a manufacturing process of a semiconductor device. In addition, a symbol (reference numeral) commonly used in each drawing indicates a common configuration even when not specifically mentioned in the description of each drawing.

### (1) Configuration of Substrate Processing Apparatus

The substrate processing apparatus 10 according to the present embodiments includes a process furnace 202 provided with a heater 207 serving as a heating structure (which is a heating device or a heating system). In addition, the process furnace 202 is provided with a process chamber 201 configured to accommodate a substrate support 215 supporting a plurality of substrates (wafers) including a substrate (wafer) 200. Hereinafter, the plurality of substrates (wafers) including the substrate (wafer) 200 may also be simply referred to as “substrates 200” or “wafers 200”. The heater 207 is of a cylindrical shape, and is vertically installed while being supported by a heater base (not shown) serving as a support plate. The heater 207 serving as the heating structure heats the substrates (wafers) 200 accommodated in the process chamber 201.

### <Outer Tube (Outer Cylinder, Outer Tube Structure) 203>

An outer tube (also referred to as an “outer cylinder” or an “outer tube structure”) 203 constituting a reaction vessel (a process vessel) is provided in an inner side of the heater 207 to be aligned in a manner concentric with the heater 207. For example, the outer tube 203 is made of a heat resistant material such as quartz (SiO2) and silicon carbide (SiC). The outer tube 203 is of a cylindrical shape with a closed upper end and an open lower end. A manifold (which is an inlet flange) 209 is provided under the outer tube 203 to be aligned in a manner concentric with the outer tube 203. For example, the manifold 209 is made of a metal such as stainless steel (SUS). The manifold 209 is of a cylindrical shape with open upper and lower ends. An O-ring 220a serving as a seal is provided between the upper end of the manifold 209 and the outer tube 203. As the manifold 209 is supported by the heater base (not shown), the outer tube 203 is installed vertically.

### <Inner Tube (Inner Cylinder, Inner Tube Structure) 204>

An inner tube (also referred to as an “inner cylinder” or an “inner tube structure”) 204 constituting the reaction vessel is provided in an inner side of the outer tube 203. For example, the inner tube 204 is made of a heat resistant material such as quartz (SiO2) and silicon carbide (SiC). The inner tube 204 is of a cylindrical shape with a closed upper end and an open lower end. The process vessel (reaction vessel) is constituted mainly by the outer tube 203, the inner tube 204 and the manifold 209. The process chamber 201 is provided in a hollow cylindrical portion of the process vessel (that is, an inside of the inner tube 204).

The process chamber 201 is configured to be capable of accommodating the wafers 200 serving as the substrates 200 in a horizontal orientation to be vertically arranged in a multistage manner by a boat 217 described later. Nozzles 410 and 420 are installed in the process chamber 201 so as to penetrate a side wall of the manifold 209 and the inner tube 204. The nozzle 410 may also be referred to as a “first nozzle”, and the nozzle 420 may also be referred to as a “second nozzle”. Gas supply pipes 310 and 320 are connected to the nozzles 410 and 420, respectively. As described above, the two nozzles 410 and 420 and the two gas supply pipes 310 and 320 are connected to the substrate processing apparatus 10, and thereby it is possible to supply various gases into the process chamber 201 through the two nozzles 410 and 420 and the two gas supply pipes 310 and 320. However, the process furnace 202 of the present embodiments is not limited to the example described above.

### <Gas Supplier>

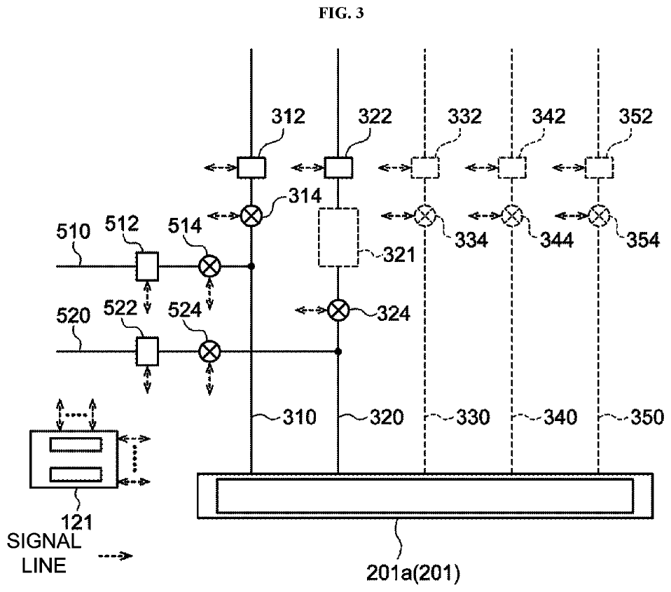

As shown in FIG. 3, mass flow controllers (MFCs) 312 and 322 serving as flow rate controllers (flow rate control structures) and valves 314 and 324 serving as opening/closing valves are sequentially installed at the gas supply pipes 310 and 320 in this order from upstream sides to downstream sides of the gas supply pipes 310 and 320 in a gas flow direction, respectively. Gas supply pipes 510 and 520 through which an inert gas is supplied are connected to the gas supply pipes 310 and 320 at downstream sides of the valves 314 and 324, respectively. MFCs 512 and 522 serving as flow rate controllers (flow rate control structures) and valves 514 and 524 serving as opening/closing valves are sequentially installed at the gas supply pipes 510 and 520 in this order from upstream sides to downstream sides of the gas supply pipes 510 and 520 in the gas flow direction, respectively.

The nozzles 410 and 420 are connected to front ends (tips) of the gas supply pipes 310 and 320, respectively. Each of the nozzles 410 and 420 may include an L-shaped nozzle. Horizontal portions of the nozzles 410 and 420 are installed so as to penetrate the side wall of the manifold 209 and the inner tube 204. Vertical portions of the nozzles 410 and 420 are installed in a preliminary chamber 201a of a channel shape (a groove shape) protruding outward in a radial direction of the inner tube 204 and extending in a vertical direction. That is, the vertical portions of the nozzles 410 and 420 are installed in the preliminary chamber 201a toward the upper end of the inner tube 204 (in a direction in which the wafers 200 are arranged) and along an inner wall of the inner tube 204. In addition, the nozzles 410 and 420 are arranged outside an opening 201b of the preliminary chamber 201a. For example, as shown by broken lines in FIG. 3, a third nozzle (not shown) and a fourth nozzle (not shown) (which are connected to gas supply pipes 330 and 340 through which a cleaning gas or the inert gas can be supplied) may also be provided.

The nozzles 410 and 420 extend from a lower region of the process chamber 201 to an upper region of the process chamber 201. The nozzles 410 and 420 are provided with a plurality of gas supply holes 410a and a plurality of gas supply holes 420a facing the wafers 200, respectively. Thereby, a gas such as a process gas can be supplied to the wafers 200 through each of the gas supply holes (openings) 410a of the nozzle 410 and each of the gas supply holes (openings) 420a of the nozzle 420.

The gas supply holes 410a are provided from a lower portion to an upper portion of the inner tube 204. An opening area of each of the gas supply holes 410a is the same, and each of the gas supply holes 410a is provided at the same pitch. However, the gas supply holes 410a are not limited thereto. For example, the opening area of each of the gas supply holes 410a may gradually increase from the lower portion to the upper portion of the inner tube 204. Thereby, it is possible to further uniformize a flow rate of the gas supplied through the gas supply holes 410a.

The gas supply holes 420a are provided from the lower portion to the upper portion of the inner tube 204. An opening area of each of the gas supply holes 420a is the same, and each of the gas supply holes 420a is provided at the same pitch. However, the gas supply holes 420a are not limited thereto. For example, the opening area of each of the gas supply holes 420a may gradually increase from the lower portion to the upper portion of the inner tube 204. Thereby, it is possible to further uniformize a flow rate of the gas supplied through the gas supply holes 420a.

The gas supply holes 410a of the nozzle 410 and the gas supply holes 420a of the nozzle 420 are provided from a lower portion to an upper portion of the boat 217 described later. Therefore, the process gas supplied into the process chamber 201 through the gas supply holes 410a of the nozzle 410 and the gas supply holes 420a of the nozzle 420 is supplied onto the wafers 200 accommodated in the boat 217 from the lower portion to the upper portion thereof, that is, an entirety of the wafers 200 accommodated in the boat 217. It is preferable that the nozzles 410 and 420 extend from the lower region to the upper region of the process chamber 201. However, the nozzles 410 and 420 may extend only to the vicinity of a ceiling of the boat 217.

A source gas containing a first metal element (also referred to as a “first metal-containing gas” or a “first source gas”) is supplied into the process chamber 201 through the gas supply pipe 310 provided with the MFC 312 and the valve 314 and the nozzle 410. The source gas serves as one of process gases. As a source material of the source gas, for example, trimethylaluminum (Al(CH3)3, abbreviated as TMA) serving as an aluminum-containing source material (which is an aluminum-containing source gas or an aluminum-containing gas) may be used. The aluminum-containing source material serves as a metal-containing source gas (which is a metal-containing gas) containing aluminum (Al) as a metal element (first metal element). The TMA is an organic source material, and is alkyl aluminum in which an alkyl group is bonded to aluminum. As another source material of the source gas, for example, a metal-containing gas (which is an organic source material) such as tetrakis ethylmethyl aminozirconium (TEMAZ, Zr[N(CH3)C2H5]4) containing zirconium (Zr) may be used. The TEMAZ is in a liquid state at the normal temperature and the normal pressure, and is vaporized by a vaporizer (not shown) to be used as TEMAZ gas serving as a vaporized gas.

A reactive gas serving as one of the process gases is supplied into the process chamber 201 through the gas supply pipe 320 provided with the MFC 322 and the valve 324 and the nozzle 420. As the reactive gas, for example, an oxygen-containing gas (which is an oxidizing gas or an oxidizing agent) serving as a reactive gas (reactant) containing oxygen (O) and reacting with aluminum may be used. As the oxygen-containing gas, for example, ozone (03) gas may be used. In addition, the gas supply pipe 320 may be provided with a flash tank 321 shown by a dotted line in FIG. 3. By providing the flash tank 321, it is possible to supply a large amount of the O3 gas) to the wafer 200.

According to the present embodiments, the source gas (which is the metal-containing gas) is supplied into the process chamber 201 through the gas supply holes 410a of the nozzle 410 and the reactive gas (which is the oxygen-containing gas) is supplied into the process chamber 201 through the gas supply holes 420a of the nozzle 420. Thereby, the source gas (that is, the metal-containing gas) and the reactive gas (that is, the oxygen-containing gas) are supplied to a surface of the wafer 200 to form a metal oxide film on the surface of the wafer 200.

The inert gas such as nitrogen (N2) gas is supplied into the process chamber 201 through the gas supply pipes 510 and 520 provided with the MFCs 512 and 522 and the valves 514 and 524, respectively, and the nozzles 410 and 420. While the present embodiments will be described by way of an example in which the N2 gas is used as the inert gas, the inert gas according to the present embodiments is not limited thereto. For example, instead of or in addition to the N2 gas, a rare gas such as argon (Ar) gas, helium (He) gas, neon (Ne) gas and xenon (Xe) gas may be used as the inert gas.

A gas supplier (which is a gas supply structure or a gas supply system) is constituted mainly by the nozzles 410 and 420. Further, a process gas supplier (which is a process gas supply structure or a process gas supply system) is constituted mainly by the gas supply pipes 310 and 320, the MFCs 312 and 322, the valves 314 and 324 and the nozzles 410 and 420. For example, at least one among the gas supply pipe 310 and the gas supply pipe 320 may be considered as the gas supplier. In addition, the process gas supplier may also be simply referred to as the “gas supplier”. When the source gas is supplied through the gas supply pipe 310, a source gas supplier (which is a source gas supply structure or a source gas supply system) is constituted mainly by the gas supply pipe 310, the MFC 312 and the valve 314. The source gas supplier may further include the nozzle 410. For example, the source gas supplier may also be referred to as a source supplier (which is a source supply structure or a source supply system). When the metal-containing source gas is used as the source gas, the source gas supplier may also be referred to as a “metal-containing source gas supplier” which is a metal-containing source gas supply structure or a metal-containing source gas supply system. Further, when the reactive gas is supplied through the gas supply pipe 320, a reactive gas supplier (which is a reactive gas supply structure or a reactive gas supply system) is constituted mainly by the gas supply pipe 320, the MFC 322 and the valve 324. The reactive gas supplier may further include the nozzle 420. For example, when the oxygen-containing gas serving as the reactive gas is supplied through the gas supply pipe 320, the reactive gas supplier may also be referred to as an “oxygen-containing gas supplier” which is an oxygen-containing gas supply structure or an oxygen-containing gas supply system. In addition, an inert gas supplier (which is an inert gas supply structure or an inert gas supply system) is constituted mainly by the gas supply pipes 510 and 520, the MFCs 512 and 522 and the valves 514 and 524. The inert gas supplier may also be referred to as a “purge gas supplier” (which is a purge gas supply structure or a purge gas supply system), a dilution gas supplier” (which is a dilution gas supply structure or a dilution gas supply system), or a carrier gas supplier” (which is a carrier gas supply structure or a carrier gas supply system).

According to the present embodiments, the gas is supplied into a vertically long annular space which is defined by the inner wall of the inner tube 204 and edges (peripheries) of the wafers 200 through the nozzles 410 and 420 provided in the preliminary chamber 201a. The gas is ejected into the inner tube 204 through the gas supply holes 410a of the nozzle 410 and the gas supply holes 420a of the nozzle 420 facing the wafers 200. Specifically, gases such as the source gas are ejected into the inner tube 204 in a direction parallel to surfaces of the wafers 200 through the gas supply holes 410a of the nozzle 410 and the gas supply holes 420a of the nozzle 420, respectively.

### <Exhauster>

An exhaust hole (which is an exhaust port) 204a is a through-hole facing the nozzles 410 and 420, and is provided at a side wall of the inner tube 204. For example, the exhaust hole 204a may be provided at a location 180° opposite to the preliminary chamber 201a, and the exhaust hole 204a may be of a narrow slit-shaped through-hole elongating vertically. Therefore, the gases (which are supplied into the process chamber 201 through the gas supply holes 410a of the nozzle 410 and the gas supply holes 420a of the nozzle 420) are supplied (or flow) over the surfaces of the wafers 200. The gases that have flowed over the surfaces of the wafers 200 are exhausted through the exhaust hole 204a into a gap (that is, an exhaust path 206) provided between the inner tube 204 and the outer tube 203. The gases flowing in the exhaust path 206 are supplied into an exhaust pipe 231, and are then discharged (exhausted) out of the process furnace 202. For example, an exhauster (which is an exhaust structure or an exhaust system) is constituted by at least the exhaust pipe 231.

The exhaust hole 204a is provided to face the wafers 200 (preferably, to face the boat 217 from the upper portion to the lower portion thereof). The gases supplied in the vicinity of the wafers 200 in the process chamber 201 through the gas supply holes 410a and the gas supply holes 420a are supplied (or flow) in the horizontal direction. The gases flows in the horizontal direction (that is, along a direction parallel to main surfaces of the wafers 200), and then are exhausted through the exhaust hole 204a into the exhaust path 206. That is, the gases remaining in the process chamber 201 are exhausted along the direction parallel to the main surfaces of the wafers 200 through the exhaust hole 204a. Further, the exhaust hole 204a is not limited to the slit-shaped through-hole. For example, the exhaust hole 204a may be configured as a plurality of holes.

The exhaust pipe 231 through which an inner atmosphere of the process chamber 201 is exhausted is installed at the manifold 209. A pressure sensor 245 serving as a pressure detector (pressure detecting structure) configured to detect an inner pressure of the process chamber 201, an APC (Automatic Pressure Controller) valve 243 and a vacuum pump 246 serving as a vacuum exhaust apparatus are sequentially installed at the exhaust pipe 231 in this order from an upstream side to a downstream side of the exhaust pipe 231 in the gas flow direction. With the vacuum pump 246 in operation, the APC valve 243 may be opened or closed to perform a vacuum exhaust of the process chamber 201 or stop the vacuum exhaust. Further, with the vacuum pump 246 in operation, an opening degree of the APC valve 243 may be adjusted in order to adjust the inner pressure of the process chamber 201. The exhauster (that is an exhaust line) is constituted mainly by the exhaust hole 204a, the exhaust path 206, the exhaust pipe 231, the APC valve 243 and the pressure sensor 245. The exhauster may further include the vacuum pump 246.

As shown in FIG. 1, a seal cap 219 serving as a furnace opening lid capable of airtightly sealing a lower end opening of the manifold 209 may be provided under the manifold 209. The seal cap 219 is in contact with the lower end of the manifold 209 from thereunder. For example, the seal cap 219 is made of a metal such as SUS, and is of a disk shape. An O-ring 220b serving as a seal is provided on an upper surface of the seal cap 219 so as to be in contact with the lower end of the manifold 209. A rotator 267 configured to rotate the boat 217 accommodating the wafers 200 is provided at the seal cap 219 in a manner opposite to the process chamber 201. A rotating shaft 255 of the rotator 267 is connected to the boat 217 through the seal cap 219. As the rotator 267 rotates the boat 217, the wafers 200 are rotated. The seal cap 219 may be elevated or lowered in the vertical direction by a boat elevator 115 serving as an elevating structure vertically provided outside the outer tube 203. When the seal cap 219 is elevated or lowered in the vertical direction by the boat elevator 115, the boat 217 may be transferred (loaded) into the process chamber 201 or transferred (unloaded) out of the process chamber 201. The boat elevator 115 serves as a transfer device (which is a transfer structure) capable of loading the boat 217 and the wafers 200 accommodated in the boat 217 into the process chamber 201 and capable of unloading the boat 217 and the wafers 200 accommodated in the boat 217 out of the process chamber 201.

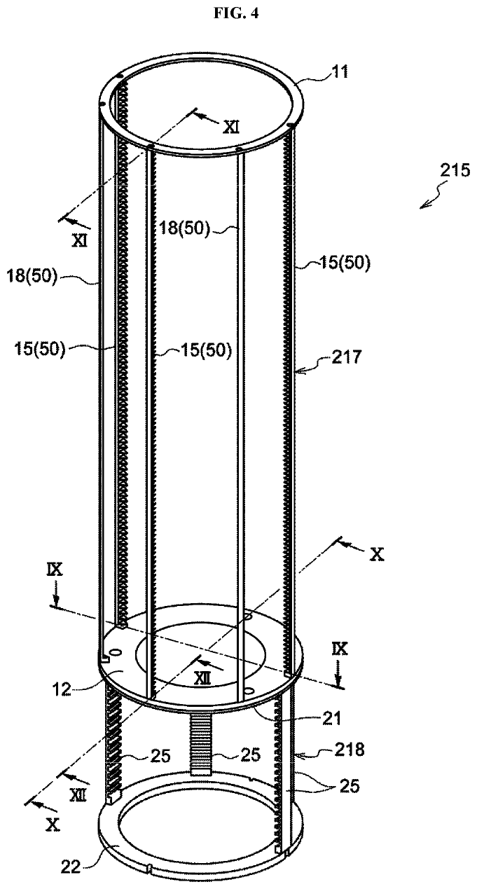

The boat 217 is configured to accommodate (or support) the wafers 200 (for example, 25 to 200 wafers) while the wafers 200 are horizontally oriented with their centers aligned with one another with a predetermined interval therebetween in a multistage manner. For example, a heat insulating plate holder 218 configured to accommodate a heat resistant material such as quartz and SiC therein is provided under the boat 217. With such a configuration, it is possible to suppress a transmission of the heat from the heater 207 to the seal cap 219. A structure in which the boat 217 is placed on the heat insulating plate holder 218 is also referred to as the “substrate support 215” (see FIG. 4), and the details thereof will be described later.

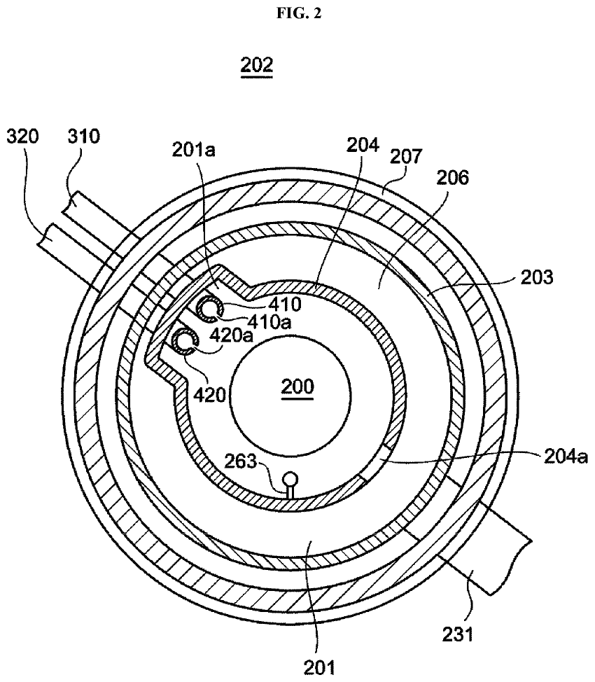

As shown in FIG. 2, a temperature sensor 263 serving as a temperature detector is installed in the inner tube 204. An amount of the current supplied (or applied) to the heater 207 is adjusted based on temperature information detected by the temperature sensor 263 such that a desired temperature distribution of an inner temperature of the process chamber 201 can be obtained. Similar to the nozzles 410 and 420, the temperature sensor 263 is L-shaped, and is provided along the inner wall of the inner tube 204.

With such a configuration, a temperature of at least a region (area) (of the boat 217) supporting the wafers 200 is maintained uniform. There is a difference between the temperature of the region (also referred to as a “soaking region T1”) whose temperature is uniform and a temperature of a region (area) (of the boat 217) provided below the soaking region T1. For example, the soaking region T1 may also be referred to as a “substrate processing region” or a “substrate processing area”. A length of the substrate processing region in the vertical direction is configured to be equal to or less than a length of the soaking region T1 in the vertical direction. In addition, the substrate processing region may refer to locations in the vertical direction of the boat 217 where the wafers 200 are supported (mounted or placed). In the present embodiments, the term “wafer” may refer to at least one among a product wafer, a dummy wafer and a fill dummy wafer. Further, the term “substrate processing region” refer to a region in the boat 217 where the wafers 200 are accommodated. That is, the substrate processing region may also be referred to as a “substrate retaining region” or a “substrate retaining area”.

### <Substrate Support 215>

As shown in FIG. 4, the substrate support 215 is of a structure in which the boat 217 is detachably installed on the heat insulating plate holder 218.

### <Boat 217>

As shown in FIG. 5, the boat 217 constituting a part of the substrate support 215 includes: a top plate 11 made of a metal material; a bottom plate 12 made of a metal material and provided parallel to the top plate 11; and a plurality of pillars including a pillar 50 made of a metal material and interposed between the top plate 11 and the bottom plate 12. Hereinafter, the plurality of pillars including the pillar 50 may also be simply referred to as “pillars 50”. The substrates 200 (see FIG. 1) are supported in a multistage manner by at least a part of the pillars 50, for example, by a plurality of support columns including a support column 15. For example, the substrates 200 are supported by three support columns 15. Hereinafter, the plurality of support columns including the support column 15 may also be simply referred to as “support columns 15”. Each of the top plate 11 and the bottom plate 12 is of a donut-like ring shape with a hole in a center thereof. A radial width of the bottom plate 12 (that is, a substantial portion of the ring shape) is greater than that of the top plate 11. In addition, relative locations between the top plate 11 and the pillars 50 and relative locations between the bottom plate 12 and the pillars 50 are positioned by a plurality of spigot structures (also referred to as “inlay structures”), as will be described later, and each of the pillars 50 and each of the pillars 50 are removably fixed to the top plate 11 and the bottom plate 12, respectively, by using a plurality of screws including a screw 70 serving as a fixing structure. Hereinafter, the plurality of screws including the screw 70 and serving as fixing structures may also be simply referred to as “screws 70”. Hereinafter, each of the plurality of spigot structures may also be referred to as a “spigot structure”.

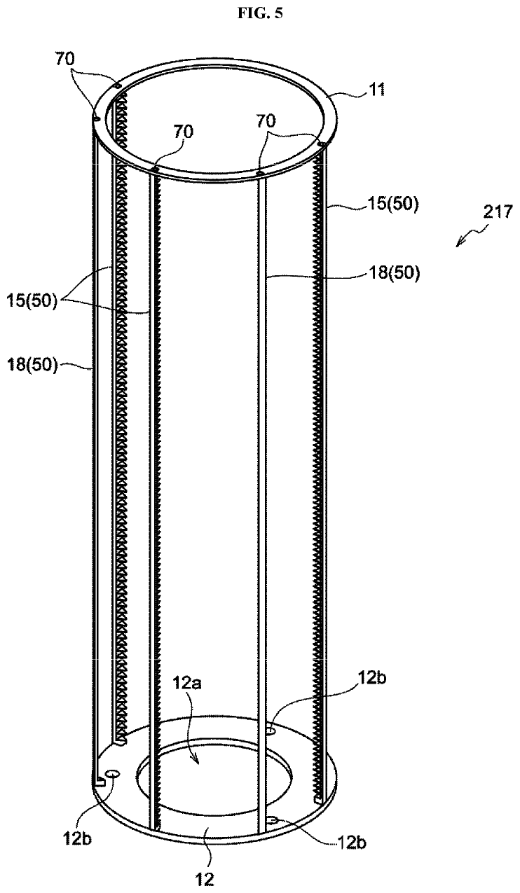

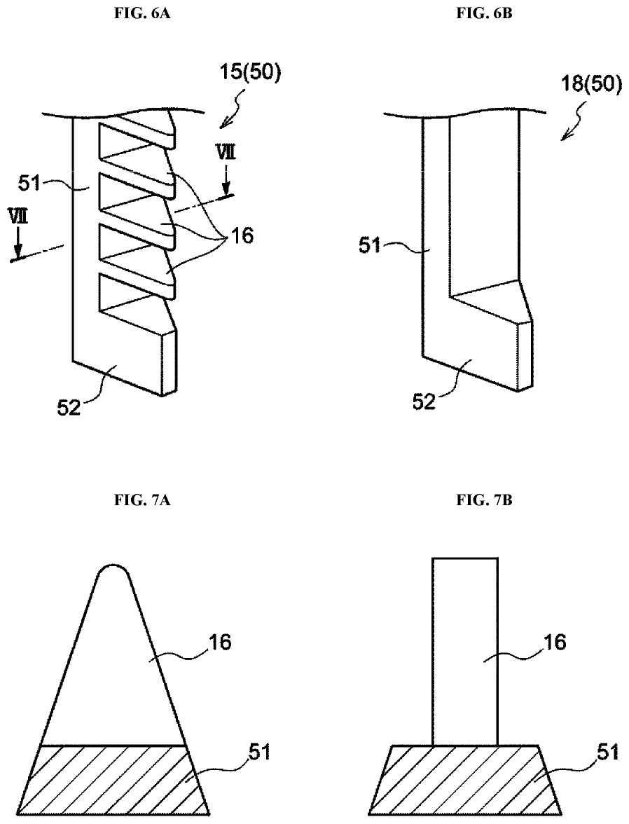

On the other hand, a plurality of auxiliary pillars including an auxiliary pillar 18 (which serve as a part of the pillars 50) are provided between the support columns 15. Hereinafter, the plurality of auxiliary pillars including the auxiliary pillar 18 may also be simply referred to as “auxiliary pillars 18”. As shown in FIG. 6B, the auxiliary pillar 18 may include a pillar main structure 51 and a mounting structure 52 in a manner similar to the support column 15. Hereinafter, the plurality of mounting structures including the mounting structure 52 may also be simply referred to as “mounting structures 52”. However, unlike the support column 15, no support structure (such as support structures 16 that will be described later) is formed on an inner surface of the pillar main structure 51. As a result, the auxiliary pillar 18 does not participate in supporting the substrates 200.

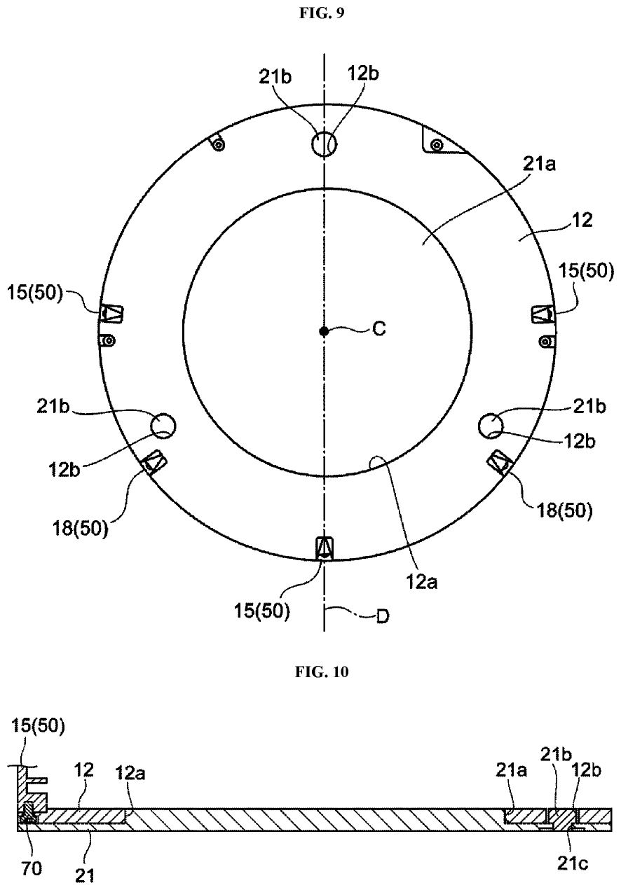

As shown in FIG. 9 (which schematically illustrates a cross-section taken along a line IX-IX shown in FIG. 4), the support columns 15 (and the auxiliary pillar 18) are arranged at positions symmetrical with respect to an imaginary reference line D perpendicular to an axis C and passing through a center of the bottom plate 12 when viewed from above. Further, in the present embodiments, two auxiliary pillars 18 are provided. However, but for example, when the number of the support columns 15 is an even number and the auxiliary pillar 18 alone is provided, the auxiliary pillar 18 may be provided on the imaginary reference line D.

As shown in FIGS. 6A and 7A, the support column 15 serving as a part of the pillar 50 is provided with the pillar main structure 51 (which connects the top plate 11 to the bottom plate 12) of a trapezoidal cross-section shape (see FIG. 7A). Further, the pillar main structure 51 is provided with a plurality of support structures including a support structure 16 (which are a large number of triangular tongue pieces projecting in a central direction at equal intervals on an inner surface of the pillar main structure 51). Hereinafter, the plurality of support structures including the support structure 16 may also be simply referred to as “support structures 16”. The support structures 16 are configured to support the substrates 200. In addition, Further, two mounting structures 52 may be provided at upper and lower ends of the pillar main structure 51, respectively. Similar to the support structure 16, the mounting structure 52 is of a planer shape, and a thickness of the mounting structure 52 is greater than that of the support structure 16.

As shown in FIG. 7A, a width of the support structure 16 when viewed from above decreases as it approaches the axis C. Thereby, it is difficult for the support structure 16 to obstruct a flow of a film forming gas supplied to the substrates 200. Further, as shown in FIG. 7B, the support structure 16 may be of a rectangular shape when viewed from above whose width is narrower than that of the pillar main structure 51. However, from the viewpoint of providing a smoother flow of the film forming gas in an axial direction, it is preferable that the support structure 16 is of a triangular shape when viewed from above as shown in FIG. 7A.

Each of the pillar 50, the support column 15 and the auxiliary pillar 18 is made of a metal material as described above. For example, it is preferable that each of the pillar 50, the support column 15 and the auxiliary pillar 18 is made of stainless steel serving as the metal material coated with a chromium oxide film (CrO film) serving as a film of a metal oxide (that is, a metal oxide film). As the stainless steel, for example, stainless steel such as SUS316L, SUS836L and SUS310S may be preferably used. A toughness of such a material is higher than that of conventional quartz or SiC and such a material is less likely to break than the conventional quartz or SiC. Therefore, it is possible to provide the pillar main structure 51 whose width is narrow. For example, when a width of a support column of a conventional boat is 19 mm, a width of the support column 15 of the boat 217 according to the present embodiments shown in FIG. 5 can be set to a width within a range from 5 mm to 10 mm.

The width of the support column 15 is set in advance such that the strength of the support structure 16 is sufficient to support the substrate (wafer) 200. Therefore, the width of the support column 15 within the range from 5 mm to 10 mm in the present embodiments is merely an example. For example, even when a diameter (that is, the width) of the support column 15 whose strength is sufficient to support the substrate (wafer) 200 is less than 5 mm depending on the number of the support columns 15, the present embodiment can be applied. That is, when the width of the support column 15 is reduced, it is difficult to obstruct the flow of the film forming gas. Thereby, a stagnation of the film forming gas is less likely to occur. In addition, since a surface area of the support column 15 is reduced, a consumption of the film forming gas is reduced. As a result, it is possible to reduce a decrease in a thickness uniformity of a film due to a thickness decrease of the film in the vicinity of each of the support columns 15.

Further, when a film forming process is preformed while the boat 217 supports the substrates 200, vibrations may occur in the boat 217. Thereby, a substrate (among the substrates 200) supported at the upper portion of the boat 217 may fall off. Such a phenomenon is noticeable when the boat 217 described above is made of a metal material whose rigidity is lower than that of the quartz. Therefore, in the present embodiment, a cross-sectional shape and a cross-sectional area of the pillar 50 are designed such that a natural frequency of a mechanical vibration in a direction of attaching or detaching the substrate 200 in the boat 217 is greater than a predetermined frequency, preferably 4 Hz. In other words, preferably, by setting the natural frequency of the boat 217 to be greater than 4 Hz, a period of the vibration can be preferably reduced to 0.25 second or less. Thereby, it is possible to suppress a large vibration of the boat 217. In order to obtain such a natural frequency, as a material of the pillar 50, it is possible to use an alloy whose Rockwell hardness (HRC) is 30 or more, which is obtained by performing a heat treatment process. In such a case, it is preferable that the pillar 50 is made of the alloy, quench the pillar 50, and then further apply the coating described above.

The top plate 11 of the boat 217 shown in FIG. 5 is provided with a plurality of through-holes 62 (see FIG. 12) (which will be described later) corresponding to the number and positions of the pillars 50. The pillars 50 are fixed to the top plate 11 through the through-holes 62 of the top plate 11 by the screws 70 serving as the fixing structures.

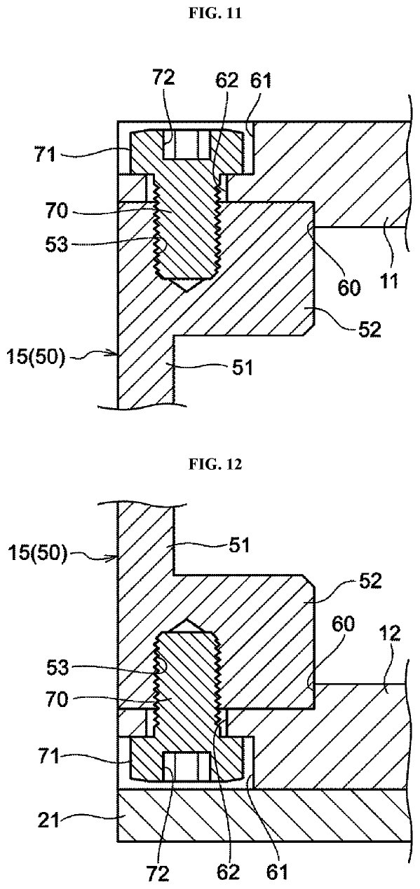

A hole provided at the center of the bottom plate 12 of the boat 217 is a pilot hole (also referred to as a “spigot hole”) 12a into which a part of the heat insulating plate holder 218 (described later) fits, which will be described later. Further, the through-holes 62 (see FIG. 11) of the bottom plate 12 described later are provided in the bottom plate 12 at the same positions as the through-holes 62 of the top plate 11 described above. The pillars 50 are fixed to the bottom plate 12 through the through-holes 62 of the bottom plate 12 by the screws 70 serving as the fixing structures. In addition, the top plate 11 is provided with a plurality of positioning holes 12b at a plurality of locations (three locations in the present embodiments). At least one of the positioning holes 12b is different in size from the others, and a significance of such a relationship will be described later.

The materials of the top plate 11 and the bottom plate 12 are not particularly limited as long as each of the top plate 11 and the bottom plate 12 is made of a metal material. However, from a viewpoint of the integrity when the top plate 11 and the bottom plate 12 are assembled as the boat 217, it is preferable that each of the top plate 11 and the bottom plate 12 is made of the same material as the pillar 50. In the present embodiments, it is preferable that the top plate 11, the bottom plate 12 and the pillars 50 (in particular, the support columns 15) are molded as individual structures from the material described above, and then each is coated with the oxide described above, and then assembled into the boat 217 by fixing with the screws 70.

### <Heat Insulating Plate Holder 218>

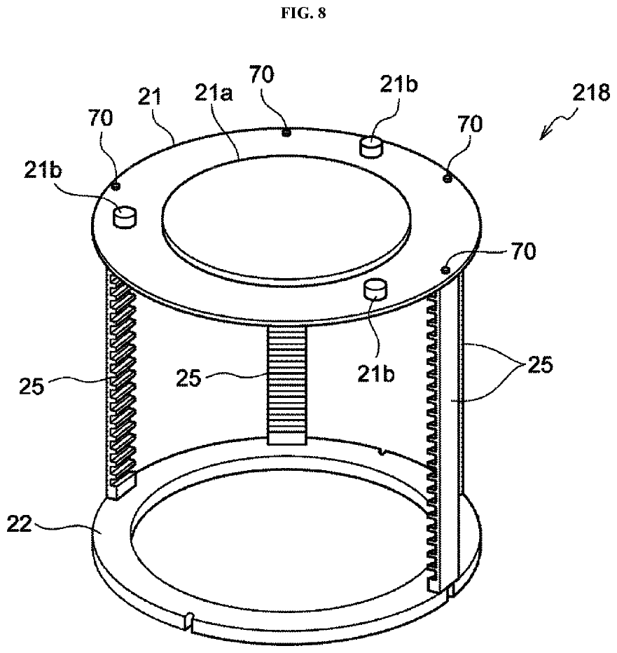

As shown in FIG. 8, the heat insulating plate holder 218 (which constitutes a part of the substrate support 215 and on which the boat 217 is placed) may include: a holder top plate 21 made of a metal material; a holder bottom plate 22 made of a metal material and provided parallel to the holder top plate 21; and a plurality of holder pillars including a holder pillar 25 made of a metal material and provided (disposed) between the holder top plate 21 and the holder bottom plate 22. Hereinafter, the plurality of holder pillars including the holder pillar 25 may also be simply referred to as “holder pillars 25”. For example, according to the present embodiments, four holder pillars are provided as the holder pillars 25. The materials of the holder top plate 21, the holder bottom plate 22 and the holder pillar 25 constituting the heat insulating plate holder 218 are not particularly limited as long as each of the holder top plate 21, the holder bottom plate 22 and the holder pillar 25 is made of a metal material. However, from a viewpoint of the integrity when the holder top plate 21, the holder bottom plate 22 and the holder pillar 25 are assembled to provide the heat insulating plate holder 218 and to provide the substrate support 215 by placing the boat 217 on the heat insulating plate holder 218, it is preferable that the heat insulating plate holder 218 is made of substantially the same material as the boat 217.

The holder top plate 21 is of a disk shape, and is provided with a spigot convex structure 21a slightly projecting upward in a cylindrical shape from a center portion of the holder top plate 21. An outer diameter of the spigot convex structure 21a is set such that the spigot convex structure 21a can fit into an inner diameter of the pilot hole 12a described above. The holder top plate 21 is provided with a plurality of through-holes (not shown) corresponding to the number and positions of the holder pillars 25. The holder pillars 25 are fixed to the holder top plate 21 through the through-holes (not shown) by the screws 70 serving as the fixing structures.

The holder top plate 21 is further provided with a plurality of pin holes 21c (see FIG. 10) at positions corresponding to the positioning holes 12b of the bottom plate 12 of the boat 217. A plurality of positioning pins 21b are attached to the pin holes 21c, respectively, and a head portion of each of the positioning pins 21b protrudes upward. An outer diameter of the head portion of each of the positioning pins 21b is set such that the head portion of each of the positioning pins 21b can fit into an inner diameter of each of the positioning holes 12b described above.

The holder bottom plate 22 is of a ring shape, and is provided with a plurality of through-holes (not shown) corresponding to the number and positions of the holder pillars 25. The holder pillars 25 are fixed to the holder bottom plate 22 through the through-holes of the holder bottom plate 22 by screws (not shown) serving as a fixing structure.

### <Positioning Between Boat 217 and Heat Insulating Plate Holder 218>

When placing the boat 217 on the heat insulating plate holder 218, the spigot convex structure 21a of the holder top plate 21 is fitted into the pilot hole 12a of the bottom plate 12 in a state where the positioning pins 21b provided on the holder top plate 21 are positioned correctly according to the positioning holes 12b provided on the bottom plate 12 of the boat 217. In FIG. 9 (which schematically illustrates the cross-section taken along the line IX-IX shown in FIG. 4 when viewed from) and in FIG. 10 (which schematically illustrates a vertical cross-section taken along a line X-X shown in FIG. 4), such a state above is illustrated. That is, the bottom plate 12 and the holder top plate 21 are positioned with respect to the axis C by a spigot structure constituted by the pilot hole 12a and the spigot convex structure 21a, and are positioned in a circumferential direction by a spigot structure constituted by the positioning holes 12b of the bottom plate 12 and positioning pins 21b of the holder top plate 21.

For example, in the present embodiments, in the positioning holes 12b and the positioning pins 21b, a size of at least one positioning hole among the positioning holes 12b (and a size of at least one positioning pin among the positioning pins 21b) may be set to be different from those of the others such that a positioning operation can be performed in a direction in which sizes of the positioning holes 12b and the positioning pins 21b match correctly. Alternatively, for example, the positioning operation can be performed by providing the positioning holes 12b and the positioning pins 21b with the same size, but providing the positioning holes 12b (and the positioning pins 21b) at asymmetrical positions when viewed from above.

For example, the boat 217 and the heat insulating plate holder 218 may be coated with the oxide described above and then assembled into the substrate support 215. Alternatively, for example, an entirety of the boat 217 and the heat insulating plate holder 218 may be coated with the oxide described above while the boat 217 is placed on the heat insulating plate holder 218.

### <Fitting Structure Among Top Plate 11 and Bottom Plate 12 and Pillar 50>

The top plate 11 and the pillars 50 are positioned by the spigot structures as described above. Specifically, as shown in FIG. 11 (which schematically illustrates a cross-section taken along a line XI-XI shown in FIG. 4), a recess 60 of a shape corresponding to a cross-section of an end portion of the pillar 50 is provided as a step on an edge of a lower surface of the top plate 11. That is, a plurality of recesses including the recess 60 are provided at the top plate 11 corresponding to the pillars 50, respectively. Further, a seat structure 61 serving as a step is provided at a location corresponding to the recess 60 at an edge of an upper surface of the top plate 11. That is, a plurality of seat structures including the seat structure 61 are provided at the top plate 11 corresponding to the recesses 60, respectively. A depth (height) of the seat structure 61 is set to be greater than a height of a screw head 71 of the screw 70 serving the fixing structure. In addition, a through-hole (among the through-holes 62) whose inner diameter is loosely fitted into a screw (among the screws 70) passes through between the seat structure 61 and the recess 60. On the other hand, a plurality of screw holes including a screw hole 53 are respectively bored at ends of the mounting structures 52 corresponding to upper ends of the pillars 50 along a longitudinal direction of each of the pillars 50. Hereinafter, the plurality of screw holes including the screw hole 53 may also be referred to as “screw holes 53”.

First, the top plate 11 and the pillars 50 are positioned by fitting the mounting structure 52 at the upper ends of the pillars 50 into the recess 60 from below. When positioning the top plate 11 and the pillars 50, the through-holes 62 of the top plate 11 and the screw holes 53 of the mounting structures 52 are positioned so as to match when viewed from above. Then, the screws 70 are respectively inserted into the screw holes 53 through the through-holes 62, and a hexagonal wrench is inserted into a hexagonal hole 72 provided at a center of the screw head 71 of each screw 70 to be screwed together. Thereby, the pillars 50 are fastened to the top plate 11 by the screws 70. When fastening the pillars 50, since the screw head 71 fits inside the seat structure 61 and does not protrude from the upper surface of the top plate 11, it is possible to reduce a possibility of direct contact with the screw 70 from the outside. Thereby, it is possible to prevent the screw 70 from loosening unexpectedly.

For example, the relative locations between the bottom plate 12 and the pillars 50 are positioned by the spigot structures as described above. Specifically, as shown in FIG. 12 (which schematically illustrates a cross-section taken along a line XII-XII shown in FIG. 4), a recess 60 of a shape corresponding to a cross-section of another end portion of the pillar 50 is provided as a step on an edge of an upper surface of the bottom plate 12. That is, a plurality of recesses including the recess 60 are provided at the bottom plate 12 corresponding to the pillars 50, respectively. Further, a seat structure 61 serving as a step is provided at a location corresponding to the recess 60 of the bottom plate 12 at an edge of a lower surface of the bottom plate 12. That is, a plurality of seat structures including the seat structure 61 are provided at the bottom plate 12 corresponding to the recesses 60, respectively. A depth (height) of the seat structure 61 of the bottom plate 12 is set to be greater than the height of the screw head 71 of the screw 70 serving the fixing structure. In addition, a through-hole (among the through-holes 62) whose inner diameter is loosely fitted into a screw (among the screws 70) passes through between the seat structure 61 of the bottom plate 12 and the recess 60 of the bottom plate 12. On the other hand, screw holes 53 are respectively bored at ends of the mounting structures 52 corresponding to lower ends of the pillars 50 along the longitudinal direction of each of the pillars 50.

First, the bottom plate 12 and the pillars 50 are positioned by fitting the mounting structure 52 at the upper ends of the pillars 50 into the recess 60 of the bottom plate 12 from below. When positioning the bottom plate 12 and the pillars 50, the through-holes 62 of the bottom plate 12 and the screw holes 53 (of the mounting structures 52) corresponding to the lower ends of the pillars 50 are positioned so as to match when viewed from above. Then, the screws 70 are respectively inserted into the screw holes 53 corresponding to the lower ends of the pillars 50 through the through-holes 62 of the bottom plate 12, and the hexagonal wrench is inserted into the hexagonal hole 72 provided at the center of the screw head 71 of each screw 70 to be screwed together. Thereby, the pillars 50 are fastened to the bottom plate 12 by the screws 70. When fastening the pillars 50, since the screw head 71 fits inside the seat structure 61 of the bottom plate 12 and does not protrude from the lower surface of the bottom plate 12, it is possible to reduce the possibility of direct contact with the screw 70 from the outside. Thereby, it is possible to prevent the screw 70 from loosening unexpectedly. Further, the screw head 71 does not interfere with a surface above which a component such as the substrate 200 is placed after the top plate 11 and the bottom plate 12 are assembled as the boat 217. Further, as shown in FIG. 4, when the boat 217 is placed on the heat insulating plate holder 218, a lower portion of the seat structure 61 of the bottom plate 12 is closed by the holder top plate 21. Thereby, even when the screw 70 becomes loose for some reason, it is possible to prevent the screw 70 from falling within the process chamber 201.

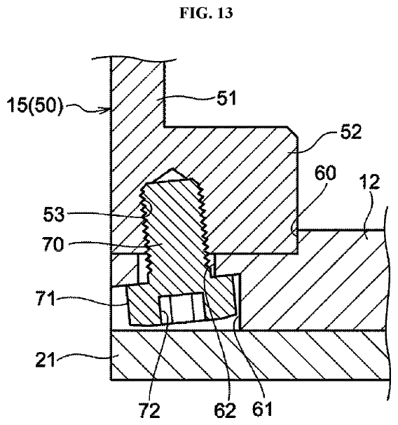

In addition, as in a modified example shown in FIG. 13, the screw hole 53 may be formed obliquely from an inside to an outside thereof, and a surface of the seat structure 61 may be provided as an inclined surface in accordance with the screw hole 53 provided obliquely. With such a configuration, the screw 70 is screwed into the screw hole 53 provided obliquely, the pillar 50 is pressed against an inner peripheral side. Thereby, it is possible to perform the positioning operation.

As described above, since the top plate 11, the bottom plate 12 and the pillars 50 are positioned using the spigot structures, it is possible to maintain a dimensional accuracy when the boat 217 is assembled. Further, since a resistance to brittle fracture of the metal material is higher than that of a conventional material (of a pillar) such as quartz and SiC, it is possible to form the pillar 50 made of the metal material with a narrower width. In addition, it is possible to prevent a film pressure of the substrate (wafer) 200 from decreasing around the pillars 50 due to the pillar 50 blocking the flow of the film forming gas when the pillar 50 is thick. Furthermore, the pillar 50 is fixed to the top plate 11 and the bottom plate 12 with the screws 70 serving the fixing structure, it is possible to replace the pillar 50 alone by releasing the fixing structure when it is preferable to replace the pillar 50, and it is also possible to change a pitch of the support structure 16.

In addition, since the boat 217 and the heat insulating plate holder 218 are provided as separate structures and positioned relative to each other by the spigot structures, it is possible to reduce an overall error due to an accumulation of dimensional tolerances of each configuration as compared with a case where the boat 217 and the heat insulating plate holder 218 are provided as a single structure, and it is also possible to improve an overall dimensional accuracy.

### <Controller 121>

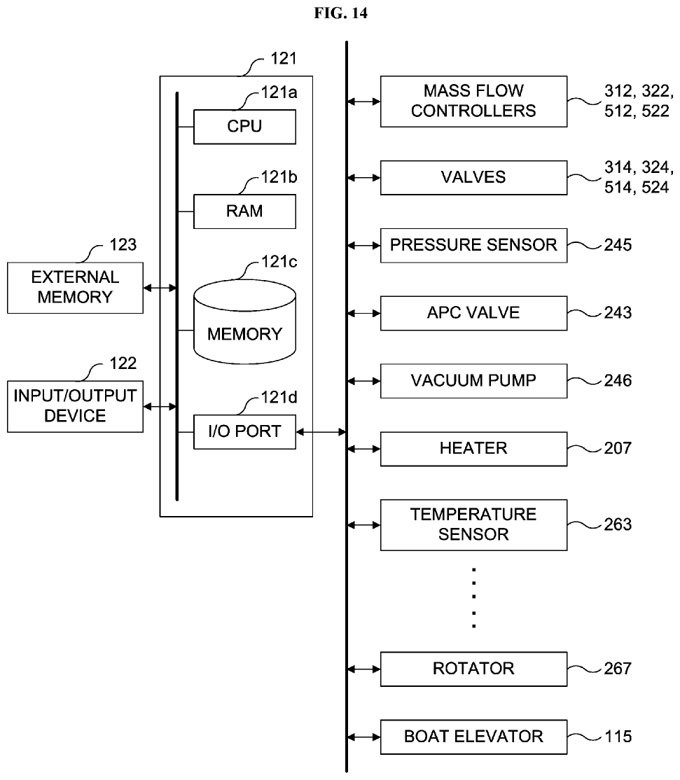

Subsequently, a configuration of a controller 121 serving as a control device (or a control structure) configured to control operations of the substrate processing apparatus 10 described above will be described with reference to FIG. 14.

As shown in FIG. 14, the controller 121 serving as the control device (or the control structure) is constituted by a computer including a CPU (Central Processing Unit) 121a, a RAM (Random Access Memory) 121b, a memory 121c and an I/O port 121d. The RAM 121b, the memory 121c and the I/O port 121d may exchange data with the CPU 121a through an internal bus. For example, an input/output device 122 constituted by a component such as a touch panel is connected to the controller 121.

For example, the memory 121c is configured by a component such as a flash memory, a hard disk drive (HDD) and a solid state drive (SSD). For example, a control program configured to control the operations of the substrate processing apparatus 10 or a process recipe containing information on sequences and conditions of a method of manufacturing a semiconductor device described later may be readably stored in the memory 121c. The process recipe is obtained by combining steps (or sequences, or process) of the method of manufacturing the semiconductor device described later such that the controller 121 can execute the steps to acquire a predetermined result, and functions as a program. Hereafter, the process recipe and the control program may be collectively or individually referred to as a “program”. In the present specification, the term “program” may refer to the process recipe alone, may refer to the control program alone, or may refer to a combination of the process recipe and the control program. The RAM 121b functions as a memory area (work area) where a program or data read by the CPU 121a is temporarily stored.

The I/O port 121d is connected to the components described above such as the MFCs 312, 322, 332, 342, 352, 512 and 522, the valves 314, 324, 334, 344, 354, 514 and 524, the pressure sensor 245, the APC valve 243, the vacuum pump 246, the heater 207, the temperature sensor 263, the rotator 267 and the boat elevator 115.

The CPU 121a is configured to read the control program from the memory 121c and execute the read control program. In addition, the CPU 121a is configured to read the process recipe from the memory 121c in accordance with an operation command inputted from the input/output device 122. In accordance with the contents of the read process recipe, the CPU 121a may be configured to control various operations such as flow rate adjusting operations for various gases by the MFCs 312, 322, 332, 342, 352, 512 and 522, opening and closing operations of the valves 314, 324, 334, 344, 354, 514 and 524, an opening and closing operation of the APC valve 243, a pressure adjusting operation by the APC valve 243 based on the pressure sensor 245, a temperature adjusting operation by the heater 207 based on the temperature sensor 263, a start operation and a stop operation of the vacuum pump 246, an operation of adjusting a rotation and a rotation speed of the boat 217 by the rotator 267, an elevating and lowering operation of the boat 217 by the boat elevator 115 and an operation of transferring and accommodating the wafer 200 into the boat 217.

The controller 121 may be embodied by installing the above-described program stored in an external memory 123 into a computer. For example, the external memory 123 may include a magnetic tape, a magnetic disk such as a flexible disk and a hard disk, an optical disk such as a CD and a DVD, a magneto-optical disk such as an MO and a semiconductor memory such as a USB memory and a memory card. The memory 121c or the external memory 123 may be embodied by a non-transitory computer readable recording medium. Hereafter, the memory 121c and the external memory 123 are collectively or individually referred to as a “recording medium”. In the present specification, the term “recording medium” may refer to the memory 121c alone, may refer to the external memory 123 alone, and may refer to both of the memory 121c and the external memory 123. Instead of the external memory 123, a communication structure such as the Internet and a dedicated line may be used for providing the program to the computer.

### (2) Substrate Processing (Manufacturing Process of Semiconductor Device)

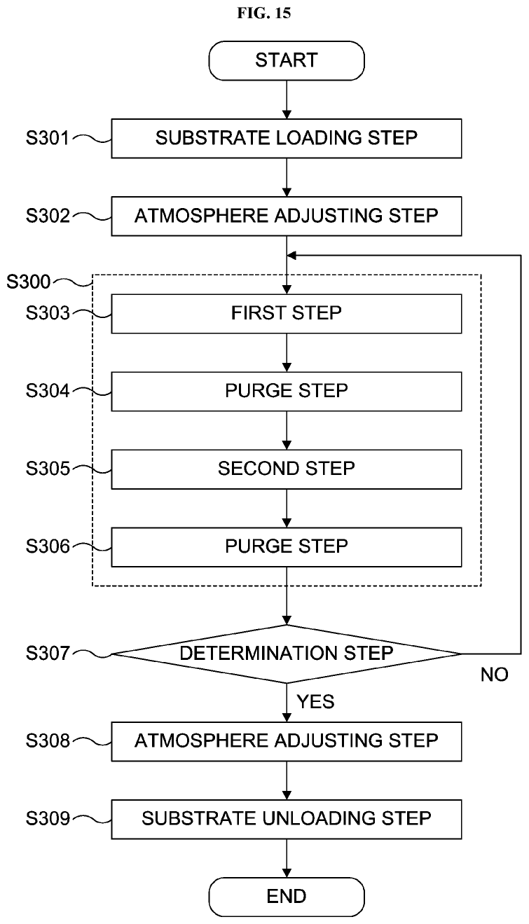

Hereinafter, as a part of the manufacturing process of the semiconductor device according to the present embodiments, an example of a substrate processing (film forming process) of forming the film on the wafer 200 will be described with reference to FIG. 15. In the following description, operations of components constituting the substrate processing apparatus 10 are controlled by the controller 121.

An example of the method of manufacturing the semiconductor device described below may include: a step of transferring (loading) the substrate support 215 described above into the process chamber 201 of the substrate processing apparatus 10 while supporting the plurality of substrates 200; a step of heating the plurality of substrates 200 loaded into the process chamber 201; and a step of transferring (unloading) the plurality of substrates 200 out of the process chamber 201 after the plurality of substrates 200 are processed in the process chamber 201. More specifically, in the following example, an aluminum oxide film (AlO film) serving as the metal oxide film is formed on the wafer 200 by performing, while heating the process chamber 201 loaded with the wafers 200 serving as the substrates at a predetermined temperature, a step of supplying the TMA gas serving as the source gas into the process chamber 201 through the plurality of gas supply holes 410a opened in the nozzle 410 and a step of supplying the O3 gas) serving as the reactive gas into the process chamber 201 through the plurality of gas supply holes 420a opened in the nozzle 420. The step of supplying the TMA gas and the step of supplying the O3 gas) are respectively performed a plurality of times to form the aluminum oxide film.

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer or a film formed on a wafer”. In the present specification, Thus, in the present specification, “forming a predetermined layer (or a film) on a wafer” may refer to “forming a predetermined layer (or a film) directly on a surface of a wafer itself”, or may refer to “forming a predetermined layer (or a film) on a surface of another layer (or another film) formed on a wafer”. In the present specification, the terms “substrate” and “wafer” may be used as substantially the same meaning.

Hereinafter, the substrate processing including a film forming step S300 will be described with reference to FIGS. 1 and 15.

### <Substrate Loading Step S301 (Wafer Charging Step and Boat Loading Step)>

The wafers 200 are charged (transferred) onto the support structure 16 of the boat 217 (wafer charging step). After the boat 217 is charged with the wafers 200, as shown in FIG. 1, the boat 217 charged with the wafers 200 is elevated by the boat elevator 115 and loaded (transferred) into the process chamber 201 (boat loading step). With the boat 217 loaded, the seal cap 219 seals the lower end opening of the manifold 209 via the O-ring 220b.

### <Atmosphere Adjusting Step S302>

Subsequently, the vacuum pump 246 vacuum-exhausts the inner atmosphere of the process chamber 201 such that the inner pressure of the process chamber 201 (that is, a pressure in a space in which the wafers 200 are accommodated) reaches and is maintained at a desired pressure (vacuum degree). Meanwhile, the inner pressure of the process chamber 201 is measured by the pressure sensor 245, and the APC valve 243 is feedback-controlled based on pressure information measured by the pressure sensor 245 (pressure adjusting step). The vacuum pump 246 continuously vacuum-exhausts the inner atmosphere of the process chamber 201 until at least a processing of the wafer 200 is completed. In addition, the heater 207 heats the process chamber 201 such that the inner temperature of the process chamber 201 reaches and is maintained at a desired temperature. Meanwhile, the amount of the current supplied to the heater 207 is feedback-controlled based on the temperature information detected by the temperature sensor 263 such that the desired temperature distribution of the inner temperature of the process chamber 201 is obtained (temperature adjusting step). The heater 207 continuously heats the process chamber 201 until at least the processing of the wafer 200 is completed. In addition, in a case where the boat 217 is rotated, the rotator 267 starts rotating the boat 217 and the wafers 200 accommodated in the boat 217. The rotator 267 continuously rotates the boat 217 and the wafers 200 until at least the processing of the wafer 200 is completed. In addition, a supply of the N2 gas serving as the inert gas to a lower portion of the heat insulating plate holder 218 through a gas supply pipe 350 may be started. Specifically, a valve 354 is opened, and a flow rate of the N2 gas is adjusted by an MFC 352 to a flow rate within a range from 0.1 slm to 2 slm. Preferably, the flow rate of the N2 gas is adjusted by the MFC 352 to a flow rate within a range from 0.3 slm to 0.5 slm.

### <Film Forming Step S300>

Subsequently, in the film forming step S300, a first step (source gas supply step) S303, a purge step (residual gas removing step) S304, a second step (reactive gas supply step) S305 and a purge step (residual gas removing step) S306 are performed a predetermined number of times (N times, wherein N is a integer equal to or greater than 1) to form the aluminum oxide film.

### <First Step (Source Gas Supply Step) S303>

The valve 314 is opened to supply the TMA gas serving as the first metal-containing gas (source gas) into the gas supply pipe 310. A flow rate of the TMA gas supplied into the gas supply pipe 310 is adjusted by the MFC 312. The TMA gas whose flow rate is adjusted is then supplied into the process chamber 201 through the gas supply holes 410a of the nozzle 410, and is exhausted through the exhaust pipe 231. Thereby, the TMA gas is supplied to the wafers 200. In the present step, in parallel with a supply of the TMA gas, the valve 514 may be opened to supply the inert gas such as the N2 gas into the gas supply pipe 510. A flow rate of the N2 gas supplied into the gas supply pipe 510 is adjusted by the MFC 512. The N2 gas whose flow rate is adjusted is then supplied into the process chamber 201 together with the TMA gas, and is exhausted through the exhaust pipe 231. The N2 gas may be further supplied into the process chamber 201 through the gas supply pipe 320 and the nozzle 420, and is exhausted through the exhaust pipe 231.

In the present step, for example, the APC valve 243 is appropriately adjusted (or controlled) such that the inner pressure of the process chamber 201 can be set to a pressure within a range from 1 Pa to 1,000 Pa, preferably from 1 Pa to 100 Pa, and more preferably from 10 Pa to 50 Pa. By setting the inner pressure of the process chamber 201 to 1,000 Pa or less, it is possible to appropriately perform the purge step (residual gas removing step) S304 described later, and it is also possible to prevent (or suppress) the TMA gas from being self-decomposed in the nozzle 410 and deposited on an inner wall of the nozzle 410. By setting the inner pressure of the process chamber 201 to 1 Pa or more, it is possible to increase a reaction rate of the TMA gas on the surfaces of the wafers 200, and it is also possible to obtain a practical deposition rate. Further, in the present specification, for example, a notation of the numerical range “from 1 Pa to 1,000 Pa” means a range equal to or higher than 1 Pa and equal to or lower than 1,000 Pa. That is, 1 Pa and 1,000 Pa are included in the numerical range described above. The same applies to other numerical ranges described herein such as a pressure, a flow rate, a time and a temperature.

For example, a supply flow rate of the TMA gas controlled by the MFC 312 can be set to a flow rate within a range from 10 sccm to 2,000 sccm, preferably from 50 sccm to 1,000 sccm, and more preferably from 100 sccm to 500 sccm. By setting the supply flow rate of the TMA gas to 2,000 sccm or less, it is possible to appropriately perform the purge step (residual gas removing step) S304 described later, and it is also possible to prevent (or suppress) the TMA gas from being self-decomposed in the nozzle 410 and deposited on the inner wall of the nozzle 410. By setting the supply flow rate of the TMA gas to 10 sccm or more, it is possible to increase the reaction rate of the TMA gas on the surfaces of the wafers 200, and it is also possible to obtain the practical deposition rate.

For example, a supply flow rate of the N2 gas controlled by the MFC 512 can be set to a flow rate within a range from 1 slm to 30 slm, preferably from 1 slm to 20 slm, and more preferably from 1 slm to 10 slm.

For example, a supply time (time duration) of supplying the TMA gas to the wafer 200 can be set to a time within a range from 1 second to 60 seconds, preferably from 1 second to 20 seconds, and more preferably from 2 seconds to 15 seconds.

For example, the heater 207 heats the process chamber 201 such that a temperature of the wafer 200 reaches and is maintained at a temperature within a range from a room temperature to 400° C., preferably from 90° C. to 400° C., and more preferably from 150° C. to 400° C. For example, the temperature of the wafer 200 is set to 400° C. or less. It is possible to change a lower limit of the temperature of the wafer 200 depending on characteristics of the oxidizing agent used as the reactive gas. Further, by setting an upper limit of the temperature of the wafer 200 to 400° C., when the substrate processing is performed by using the boat 217 described in the embodiments described above or modified examples thereof, it is possible to more reliably prevent an occurrence of a metal contamination to the wafer 200.

By supplying the TMA gas into the process chamber 201 in accordance with process conditions described above, an aluminum (Al)-containing layer is formed on an uppermost surface of the wafer 200. The aluminum-containing layer may be an aluminum layer or may be a layer containing aluminum and other elements such as carbon (H) and hydrogen (H). For example, the aluminum-containing layer may be formed on the uppermost surface of the wafer 200 by a physical adsorption of TMA, a chemical adsorption of a substance generated by decomposing a part of the TMA, or a deposition of aluminum due to a thermal decomposition of the TMA. That is, the aluminum-containing layer may be an adsorption layer (a physical adsorption layer or a chemical adsorption layer) of the TMA or the substance generated by decomposing a part of the TMA, or may be a deposition layer of aluminum (that is, the aluminum layer).

<Purge step S304 (Residual Gas Removing Step)>

After the aluminum-containing layer is formed, the valve 314 is closed to stop the supply of the TMA gas. In the present step, with the APC valve 243 open, the vacuum pump 246 vacuum-exhausts the inner atmosphere of the process chamber 201 to remove a residual gas in the process chamber 201 (that is, the TMA gas which did not react or which contributed to a formation of the aluminum-containing layer) from the process chamber 201. In the present step, by maintaining the valves 514 and 524 open, the N2 gas is continuously supplied into the process chamber 201. The N2 gas serves as a purge gas, which improves an efficiency of removing the residual gas (the TMA gas which did not react or which contributed to a formation of the aluminum-containing layer) out of the process chamber 201.

Subsequently, the second step (reactive gas supply step) S305 is performed.

### <Second Step S305 (Reactive Gas Supply Step)>

After the substance in the process chamber 201 such as the residual gas is removed, the valve 324 is opened to supply the O3 gas) serving as the reactive gas into the gas supply pipe 320. A flow rate of the O3 gas) is adjusted by the MFC 32112. The O3 gas) whose flow rate is adjusted is then supplied into the process chamber 201 through the gas supply holes 420a of the nozzle 420, and is exhausted through the exhaust pipe 231. Thereby, in the present step, the O3 gas) is exposed to the wafer 200. In the present step, the valve 524 may be opened to supply the N2 gas into the gas supply pipe 520. The flow rate of the N2 gas is adjusted by the MFC 522. The N2 gas whose flow rate is adjusted is then supplied into the process chamber 201 together with the O3 gas), and is exhausted through the exhaust pipe 231. The N2 gas may be further supplied into the process chamber 201 through the gas supply pipe 510 and the nozzle 410, and is exhausted through the exhaust pipe 231. When the flash tank 321 is provided at the gas supply pipe 320 at the upstream side of the valve 324, the O3 gas) stored in the flash tank 321 is supplied into the process chamber 201 by opening the valve 324.

The O3 gas) reacts with at least a portion of the aluminum-containing layer formed on the wafer 200 in the first step S303. The aluminum-containing layer is oxidized to form an aluminum oxide layer (AlO layer) containing aluminum (Al) and oxygen (O) and serving as a metal oxide layer. That is, the aluminum-containing layer is modified into the aluminum oxide layer.

<Purge step S306 (Residual Gas Removing Step)>

After the aluminum oxide layer is formed, the valve 324 is closed to stop the supply of the O3 gas). In the present step, a residual gas in the process chamber 201 (that is, the O3 gas) which did not react or which contributed to a formation of the aluminum oxide layer) and reaction by-products are removed from the process chamber 201 in the same manners as in the residual gas removing step S304 performed after the source gas supply step S303.

### <Performing Predetermined Number of Times>

By performing a cycle wherein the first step S303, the purge step S304, the second step S305 and the purge step S306 are performed in this order the predetermined number of times (N times), the aluminum oxide film is formed on the wafer 200. The number of executions of the cycle may be appropriately selected in accordance with a desired thickness of the aluminum oxide film finally formed. In a determination step S307, it is determined whether or not the cycle is performed the predetermined number of times. When it is determined that the cycle is performed the predetermined number of times (“YES” in FIG. 15), the film forming step S300 is terminated. When it is determined that the cycle is not performed the predetermined number of times (“NO” in FIG. 15), the film forming step S300 is repeatedly performed. It is preferable that the cycle is repeatedly performed a plurality of times in the film forming step S300. For example, the thickness of the aluminum oxide film is set to a thickness within a range from 10 nm to 150 nm, preferably from 40 nm to 100 nm, and more preferably from 60 nm to 80 nm. By setting thickness of the aluminum oxide film to 150 nm or less, it is possible to reduce a surface roughness of the aluminum oxide film, and by setting thickness of the aluminum oxide film to 10 nm or more, it is possible to suppress an occurrence of a film peeling due to a stress difference with a base film (underlying film) of the aluminum oxide film.

<Atmosphere Adjusting Step S308 (after-Purge Step and Returning to Atmospheric Pressure Step>

After the film forming step S300 is completed, by opening the valves 514 and 524, the N2 gas is supplied into the process chamber 201 through each of the gas supply pipes 310 and 320, and is exhausted through the exhaust pipe 231. The N2 gas serves as the purge gas. Thus, the residual gas in the process chamber 201 or the reaction by-products remaining in the process chamber 201 is removed from the process chamber 201 (after-purge step). Thereafter, the inner atmosphere of the process chamber 201 is replaced with the N2 gas (substitution by N2 gas), and the inner pressure of the process chamber 201 is returned to a normal pressure (atmospheric pressure) (returning to atmospheric pressure step).

### <Substrate Unloading Step S309 (Boat Unloading and Wafer Discharging Step)>

Thereafter, the seal cap 219 is lowered by the boat elevator 115 and the lower end opening of the manifold 209 is opened. The boat 217 with the processed wafers 200 charged therein is unloaded out of the outer tube 203 through the lower end opening of the manifold 209 (boat unloading step). Then, the processed wafers 200 are discharged (transferred) out of the boat 217 (wafer discharging step) after the boat 217 is unloaded out of the outer tube 203.

By performing the substrate processing described above, it is possible to deposit a desired film on the wafer 200. That is, it is possible to improve a processing uniformity of each of the wafers 200 supported by the boat 217, and it is also possible to improve the processing uniformity of the wafer 200 on the surface of the wafer 200.

### Other Embodiments of Present Disclosure

While the technique of the present disclosure is described in detail by way of the embodiments described above, the technique of the present disclosure is not limited thereto.

For example, the embodiments described above are described by way of an example in which the reaction vessel (process vessel) is constituted by the outer tube (the outer cylinder or the outer tube structure) 203 and the inner tube (the inner cylinder or the inner tube structure) 204. However, the reaction vessel may be constituted by the outer tube 203 alone.

For example, the embodiments described above are described by way of an example in which the TMA gas is used as the aluminum-containing gas. However, the technique of the present disclosure is not limited thereto. As the aluminum-containing gas, for example, a gas such as aluminum chloride (AlCl3) may be used. For example, the embodiments described above are described by way of an example in which the O3 gas) is used as the oxygen-containing gas. However, the technique of the present disclosure is not limited thereto. As the oxygen-containing gas, for example, a gas such oxygen (O2), water (H2O), hydrogen peroxide (H2O2) and a combination of O2 plasma and hydrogen (H2) plasma may also be used. For example, the embodiments described above are described by way of an example in which the N2 gas is used as the inert gas. However, the technique of the present disclosure is not limited thereto. As the inert gas, for example, a rare gas such as argon (Ar) gas, helium (He) gas, neon (Ne) gas and xenon (Xe) gas may be used.

For example, the embodiments described above are described by way of an example in which the aluminum-containing gas is used as the first gas. However, the technique of the present disclosure is not limited thereto. As the first gas, for example, a gas such as a gas containing silicon (Si) element, a gas containing titanium (Ti) element, a gas containing tantalum (Ta) element, a gas containing zirconium (Zr) element, a gas containing hafnium (Hf) element, a gas containing tungsten (W) element, a gas containing niobium (Nb) element, a gas containing molybdenum (Mo) element, a gas containing yttrium (Y) element, a gas containing lanthanum (La) element and a gas containing strontium (Sr) element may be used. Further, as the first gas, for example, a gas containing a plurality of elements exemplified above in the present disclosure may be used. In addition, as the first gas, for example, a plurality of gases containing one of the elements exemplified above in the present disclosure may be used.

For example, the embodiments described above are described by way of an example in which the oxygen-containing gas is used as the second gas. However, the technique of the present disclosure is not limited thereto. As the second gas, for example, a gas such as a gas containing nitrogen (N) element, a gas containing hydrogen (H) element, a gas containing carbon (C) element, a gas containing boron (B) element and a gas containing phosphorus (P) element may be used. Further, as the second gas, for example, a gas containing a plurality of elements exemplified above in the present disclosure may be used. In addition, as the second gas, for example, a plurality of gases containing one of the elements exemplified above in the present disclosure may be used.

For example, the embodiments described above are described by way of an example in which the first gas and the second gas are supplied sequentially. However, the substrate processing apparatus 10 of the present disclosure may be configured such that a timing at which the first gas and the second gas are supplied in parallel can be provided. In a process of supplying the first gas and the second gas in parallel, it is possible to significantly increase a film forming rate. Thereby, it is possible to shorten a time of the film forming step S300 can be shortened, and it is also possible to improve a manufacturing throughput of the substrate processing apparatus 10.

For example, the embodiments described above are described by way of an example in which the aluminum oxide film is formed on the substrate. However, the technique of the present disclosure is not limited thereto. For example, the technique of the present disclosure may also be applied when other types of films are formed. By appropriately combining the gases described above, for example, the technique of the present disclosure may also be applied to form a film containing at least one selected from the group of titanium (Ti), zirconium (Zr), hafnium (Hf), tantalum (Ta), niobium (Nb), molybdenum (Mo), tungsten (W), yttrium (Y), lanthanum (La), strontium (Sr) and silicon (Si), may also be applied to form a film (such as a nitride film, a carbonitride film, an oxide film, an oxycarbide film, an oxynitride film, an oxycarbonitride film, a boronitride film, a borocarbonitride film and a metal monomer film) containing at least one element exemplified above, or may also be applied to form a film containing at least one element exemplified above without containing other elements.

For example, the embodiments described above are described by way of an example in which a process (film forming process) of forming the film deposited on the substrate is performed. However, the technique of the present disclosure is not limited thereto. For example, the technique of the present disclosure may also be applied to perform other processes. For example, the wafer 200 may be processed by supplying the second gas (reactive gas) alone to the wafer 200. By supplying the second gas alone to the wafer 200, it is possible to perform a process such as an oxidation process on the surface of the wafer 200. In such a case, it is possible to suppress the deterioration (oxidation) of structures provided in a low temperature region.

For example, the embodiments described above are described by way of an example in which a vertical type substrate processing apparatus capable of simultaneously processing a plurality of substrates is used. However, the technique of the present disclosure may also be applied when a single wafer type substrate processing apparatus capable of processing one substrate at once is used.

For example, the embodiments described above are described by way of an example in which the film-forming process (which is a part of the manufacturing process of the semiconductor device) is performed as the substrate processing in the substrate processing apparatus 10. For example, the technique of the present disclosure may also be applied to perform another substrate processing. In addition to or instead of the substrate processing performed as a part of the manufacturing the semiconductor device, for example, the technique of the present disclosure may also be applied to perform other substrate processing such as a substrate processing performed as a part of a manufacturing process of a display device and a substrate processing performed as a part of a manufacturing process of a ceramic substrate.

### EXAMPLES

An effect of a shape of the support column 15 on preventing the wafers 200 from falling off the boat 217 is verified.

### (1) Examples and Comparative Example

In a first example and a second example according to the embodiments of the present disclosure, as shown in FIG. 6A, the support structure 16 of the support column 15 is of a triangular shape when viewed from above. On the other hand, in a comparative example, the support structure 16 of the support column 15 is of a rectangular shape when viewed from above, and the cross-section of the support column 15 is also of a rectangular shape. In each of the examples and the comparative example, an outer diameter of each of the top plate 11 and the bottom plate 12 is set to 312 mm, and a height of the boat 217 is set to approximately 990 mm. In addition, each of the support column 15, the top plate 11 and the bottom plate 12 is made of SUS316L stainless steel.

### (2) Natural Frequency Measurement

The natural frequency f of the vibration in the direction of attaching or detaching the wafer 200 (a direction along the reference line D shown in FIG. 9) is calculated by using a computer simulation. The frequency corresponds to zero-order mode vibration in which the bottom plate 12 is fixed and the top plate 11 swings in the direction along the reference line D, and is the lowest among the natural frequencies. When a total amplitude is represented by k (mm) and an acceleration is represented by a (G), the following “Formula 1” generally holds true. Therefore, the lower the frequency, the larger the amplitude tends to be.

f=½π*(19.6α/λ*103)0.5 [Formula 1]

### (3) Wafer Falling Off Test

After actually performing the film forming process corresponding to FIG. 15 in a state where a maximum number of the wafers capable of being accommodated in the boat 217 are accommodated as the wafers 200 in the boat 217, it is observed whether or not the wafers 200 fall off. In such a case, the wafers 200 are exposed to the vibrations of the boat elevator 115 during a step such as the substrate loading step S301, and are exposed to the vibrations caused by the rotation of the boat 217 and the flow of the gas during a step such as the film forming step S300.

### (4) Results

With respect to each of the comparative example, the first example and the second example, the following “Table 1” shows results of each evaluation item of the width of the pillar 50 (mm), an area (mm2) of the support structure 16, the natural frequency (Hz) and whether or not the wafers 200 fall off. For example, the area of the support structure 16 refers to an area in contact with the gas, and may include an area of an inner circumferential surface of the support column 15 with a height of one stage of the support structure 16 and may exclude an area of a portion of the support structure 16 covered by the wafer 200.

TABLE 1

| | Comparative | First | Second |
|---|---|---|---|
| Evaluation Item | Example | Example | Example |
| Width of Pillar (mm) | 8 | 11 | 15 |
| Area of Support Structure | 34 | 35 | 45 |
| (mm2) | | | |
| Natural Frequency (Hz) | 4.0 | 6.9 | 9.1 |
| Whether or Not Wafers Fall Off | YES | NO | NO |

According to the results shown above, as compared with the comparative example in which the support structure 16 is of a rectangular shape, in both of the first example and the second example in which the support structure 16 is of a triangular shape, the natural frequency is high, and an effect of suppressing the large vibration of the boat 217 is improved. As a result, the effect of preventing the wafers 200 from falling off is also improved.

The technique of the present disclosure can be used for manufacturing the semiconductor device in the substrate processing apparatus.

According to some embodiments of the present disclosure, it is possible to provided a technique capable of suppressing the thickness decrease of the film around the pillar of the substrate support by reducing the width of the pillar of the substrate support and capable of improving the thickness uniformity of the film.

What is claimed is:

1. A substrate support comprising:
a top plate made of a metal material;
a bottom plate made of a metal material; and
a plurality of pillars made of a metal material and provided between the top plate and the bottom plate,
wherein a plurality of substrates are supported in a multistage manner by at least a part of the plurality of pillars,
wherein relative locations between the top plate and the plurality of pillars and relative locations between the bottom plate and the plurality of pillars are positioned by a plurality of spigot structures, and
wherein each of the plurality of pillars and each of the plurality of pillars are removably fixed to the top plate and the bottom plate, respectively, by using a plurality of fixing structures.

2. The substrate support of claim 1, further comprising:
a boat comprising the top plate, the bottom plate and the plurality of pillars; and
a heat insulating plate holder on which the boat is detachably installed.

3. The substrate support of claim 2, wherein the heat insulating plate holder comprises:
a holder top plate made of a metal material;
a holder bottom plate made of a metal material; and
a plurality of holder pillars made of a metal material and provided between the holder top plate and the holder bottom plate.

4. The substrate support of claim 3, wherein the boat is placed on the heat insulating plate holder after the bottom plate and the holder top plate are positioned by the plurality of spigot structures.

5. The substrate support of claim 3, wherein the plurality of fixing structures comprise a plurality of screws, and
wherein a plurality of seat structures are provided on an upper surface of the bottom plate at locations corresponding to the plurality of screws, a height of each of the plurality of seat structures is set to be greater than a height of a screw head of each of the plurality of screws, the screw head of each of the plurality of screws fits inside each of the plurality of seat structures, and a lower portion of each of the plurality of seat structures is closed by the holder top plate.

6. The substrate support of claim 2, wherein the plurality of fixing structures comprise a plurality of screws, and
wherein a plurality of seat structures are provided on an upper surface of the bottom plate at locations corresponding to the plurality of screws, a height of each of the plurality of seat structures is set to be greater than a height of a screw head of each of the plurality of screws, and the screw head of each of the plurality of screws fits inside each of the plurality of seat structures.

7. The substrate support of claim 2, wherein the plurality of fixing structures comprise a plurality of screws, and
wherein the top plate, the bottom plate and the plurality of pillars are formed as individual structures coated with an oxide.

8. The substrate support of claim 2, wherein an entirety of the boat and the heat insulating plate holder are coated with an oxide while the boat is placed on the heat insulating plate holder.

9. The substrate support of claim 2, wherein a natural frequency of a mechanical vibration in a direction of attaching or detaching the plurality of substrates in the boat is greater than 4 Hz.

10. The substrate support of claim 2, wherein each of the plurality of pillars is made of an alloy whose Rockwell hardness (HRC) is 30 or more by performing a heat treatment process.

11. The substrate support of claim 1, wherein the plurality of pillars comprise:
a plurality of support columns configured to support the plurality of substrates in the multistage manner; and
a plurality of auxiliary pillars without participating in supporting the plurality of substrates,
wherein the plurality of support columns are arranged at positions symmetrical with respect to an imaginary reference line perpendicular to an axis and passing through a center of the bottom plate when viewed from above, and the plurality of auxiliary pillars are arranged at positions symmetrical with respect to the imaginary reference line when viewed from above.

12. The substrate support of claim 11, each of the plurality of support columns is provided with a plurality of support structures configured to respectively support the plurality of substrates, and a width of each of the plurality of support structures when viewed from above decreases as each of the plurality of support structures approaches the axis.

13. The substrate support of claim 1, wherein the plurality of spigot structures between the top plate and the plurality of pillars and between the bottom plate and the plurality of pillars are configured such that the plurality of pillars respectively fit into a plurality of recesses provided at an edge of the top plate or an edge of the bottom plate, each of the plurality of recesses being formed of a shape corresponding to a cross-section of an end portion of each of the plurality of pillars.

14. The substrate support of claim 1, wherein the plurality of fixing structures comprise a plurality of screws, and
wherein the plurality of screws are respectively inserted into a plurality of screw holes respectively provided at ends of the plurality of pillars along a longitudinal direction of each of the plurality of pillars through a plurality of through-holes provided at the top plate or the bottom plate such that the plurality of pillars are fastened to the top plate or the bottom plate.

15. The substrate support of claim 1, wherein the plurality of fixing structures comprise a plurality of screws, and
wherein the top plate, the bottom plate and the plurality of pillars are formed as individual structures coated with an oxide.

16. A substrate processing apparatus comprising:
the substrate support of claim 1;
a process chamber in which the substrate support supporting a plurality of substrates is accommodated; and
a heater configured to heat the plurality of substrates accommodated in the process chamber.

17. A method of manufacturing a semiconductor device, comprising:
(a) loading the substrate support of claim 1 into a process chamber of a substrate processing apparatus while a plurality of substrates are supported by the substrate support;
(b) heating the plurality of substrates loaded into the process chamber; and
(c) unloading the plurality of substrates having been processed in the process chamber from the process chamber.
